(19) United States
(12) Patent Application Publication
(10) Pub. No.: US 2026/0156774 A1
(43) Pub. Date: Jun. 4, 2026

(54) CONFIGURABLE HEAT SINK FOR POWER INVERTERS

(71) Applicant: Caterpillar Inc., Peoria, IL (US)

(72) Inventor: Johnson David Sugidharan, Tamilnadu (IN)

(73) Assignee: Caterpillar Inc., Peoria, IL (US)

(21) Appl. No.: 18/968,767

(22) Filed: Dec. 4, 2024

(51) Int. Cl. H05K 7/20

(52) U.S. Cl. CPC H05K 7/20254; H05K 7/20272; H05K 7/20927

(57) ABSTRACT

A configurable heat sink for power inverters is provided for dissipating heat generated by an associated power inverter. The configurable heat sink may include coolant fluid channels inside a heat sink body through which coolant fluid circulates. A first manifold includes a single inlet/outlet orifice through which coolant fluid enters the heat sink body and a single inlet/outlet orifice through which heated coolant fluid exits the heat sink body. A second manifold includes three inlet/outlet orifices. Coolant fluid may pass into the heat sink body via two of the inlet/outlet orifices and out of the third inlet/outlet orifice or into one of the three inlet/outlet orifices and out of the other two inlet/outlet orifices. Turbulators or channel fins may be installed or extruded into the coolant fluid channels for causing coolant fluid to experience turbulent flow though the heat sink.

### TECHNICAL FIELD

The present disclosure relates to heat sinks for removing heat from electronic and/or mechanical systems. More particularly, the present disclosure relates to a configurable heat sink for dissipating heat from a power inverter.

### BACKGROUND

A variety of electrical and mechanical systems use or are associated with electrical power generators for generating electrical power for a number of uses. Work machines such as earthmoving equipment, automobiles, trucks, recreational vehicles, and the like utilize generator systems for generating power used for powering onboard electrical systems and/or electrical propulsion systems. Standalone electrical power generators are used for generating power for houses, offices, hospitals, and the like. Such power generation systems often utilize power inverters that convert direct current (DC) to alternating current (AC) for use by any number of devices that are charged or operated with alternating current. In some cases, AC power is generated and received from onboard or standalone generators and is converted to DC power for use by DC power-enabled systems. In other cases, the AC power generated and received from onboard or standalone generators is converted to DC power, and then some or all of the DC power is then converted back to AC power for use by AC power-enabled systems (e.g., AC motors).

One undesired output of typical power inverters is heat. Power inverters heat up during the process of converting DC power to AC power. If left unchecked, the heat produced by a power inverter can damage components of the power inverter and/or cause the power inverter to operate in an inefficient manner. Power inverters are cooled using a variety of cooling systems such as cooling fans, heat sinks and thermal materials (e.g., pads, greases, oils, gap fillers, etc.).

In the case of heat sinks, heat is transferred from a power inverter to a fluid such as air or liquid coolant (e.g., water or chemical coolant liquids). Heat sinks may be constructed according to a number of different designs, but typically include one or more tubes or channels through which a fluid flows. Heat from the power inverter is transferred from components of the power inverter to the fluid which may then be cooled by exposing the heated fluid to a cooling mechanism such as exposing the heat sink to cooling air from a fan or by moving the heat sink through a cooler medium when the heat sink on a machine or vehicle in which the power inverter is operated is moved at varying speeds. Alternatively, the fluid passing through a heat sink may be cooled via a fluid cooling system such as a heating, ventilation, and cooling (HVAC) system.

According to different sizes and implementations of power inverters, a number of different configurations of heat sinks are utilized for dissipating heat from power inverters. As heat sinks are constructed from different materials and according to different manufacturing methods, costs and complexities of heat sink design and production can vary greatly and often require varying design implementations depending on use in different power inverter systems.

An example heat sink is described in European Patent Application No. EP3886146A1 to Bikmukhametov titled “Heat Sink” (hereafter “the '146 document”). The '146 document describes a heat sink having multiple coolant channels defining a coolant flow from an inlet to an outlet. Each of the coolant channels comprises cavities formed alternatingly in an upper part and lower part of the heat sink. The heat sink of the '146 document requires use of both an inlet and an outlet, and the production of the alternatingly disposed cooling channels is complex in design and expensive in production. In addition, the heat sink of the '146 document must be produced according to different sizes according to different use cases.

Examples of the present disclosure are directed to overcoming the deficiencies described above.

### SUMMARY OF THE INVENTION

Devices and methods provide a heat sink body, the heat sink body defining an open space in an interior of the heat sink body for receiving one or more fluid channels. A plate is affixed to a first end of the heat sink body, the plate having a plurality of slots fluidly connected to respective fluid channels of the one or more fluid channels. An end cap is affixed to a second end of the heat sink body. A manifold is affixed to the first end of the heat sink body, the plate disposed between the manifold and the first end of the heat sink body. The manifold includes one or more inlet/outlet orifices providing fluid passage into the one or more fluid channels, and one or more inlet/outlet orifices providing fluid exit from the one or more fluid channels. The manifold may be a cast manifold and may be affixed to the heat sink body with a structural adhesive, by a brazing process or other suitable connection method.

According to examples, each of the inlet/outlet orifices may be used as either an inlet or outlet orifice. A single inlet and single outlet orifice configuration results in a serpentine fluid flow path through the heat sink body. In the case of a three inlet/outlet configuration, two inlet orifices may be used with a single outlet orifice disposed between the two inlet orifices, or two outlet orifices may be used with a single inlet orifice disposed between the two outlet orifices. In either case, a parallel fluid flow path is provided through the heat sink body.

Each of one or more fluid channels may include a turbulator, the turbulator configured to cause a fluid passing through each of one or more fluid channels to form a turbulent flow. Alternatively, each of the one or more fluid channels may have one or more channel fins, the one or more channel fins configured to cause a fluid passing through each of the one or more fluid channels to form a turbulent flow.

The heat sink body is configured for insertion into an interior of a power inverter. One or more external surfaces of the heat sink body are configured to absorb heat from the interior of the power inverter. The heat from the interior of the power inverter may be transferred from the one or more external surfaces of the heat sink body to a coolant fluid passing through the one or more fluid channels.

According to another example, a configurable heat sink manifold is provided. The configurable heat sink manifold includes a manifold body, the manifold body configured for attachment to a first end of a heat sink body. The manifold body includes a first inlet/outlet orifice providing fluid passage into a fluid channel disposed in an interior of the heat sink body. The manifold body also includes an inlet/outlet orifice providing fluid passage out of the fluid channel disposed in the interior of the heat sink body. The first inlet/outlet orifice, the second inlet/outlet orifice, and the fluid channel provide a serpentine fluid flow path from the first inlet/outlet orifice through the fluid channel and out through the second inlet/outlet orifice.

According to another example, a method of constructing a heat sink is provided. A number and configuration of one or more fluid channels for disposition in a heat sink body is determined. A plate is selected for the determined number and configuration of one or more fluid channels for disposition in an interior of a heat sink body. The one or more fluid channels in the interior of a heat sink body are disposed. A manifold is selected for passing a coolant fluid into the one or more fluid channels in the interior of the heat sink body. The manifold is attached to a first end of the heat sink body over the selected plate.

Selecting a manifold for passing a coolant fluid into the one or more fluid channels in the interior of the heat sink body may include selecting a manifold including a first inlet/outlet orifice providing fluid passage into the one or more fluid channels in the interior of a heat sink body and includes a second inlet/outlet orifice providing fluid exit from the one or more fluid channels in the interior of a heat sink body. Selecting a manifold including a first inlet/outlet orifice providing fluid passage into the one or more fluid channels in the interior of a heat sink body and including a second inlet/outlet orifice providing fluid exit from the one or more fluid channels in the interior of a heat sink body includes selecting a manifold provides a serpentine fluid flow path from the first inlet/outlet orifice through the one or more fluid channels in the interior of a heat sink body and out through the second inlet/outlet orifice. As mentioned above, each of the first and second inlet/outlet orifices may be used for fluid flow inlet or outlet, and the direction of the serpentine fluid flow path will be reversed depending on which of the first and second inlet/outlet orifices is used for fluid flow inlet versus outlet.

Alternatively, selecting a manifold for passing a coolant fluid into the one or more fluid channels in the interior heat sink body may include selecting a manifold having a three inlet/outlet configuration where coolant fluid passes into two inlet/outlet orifices and out of a single inlet/outlet orifice disposed between the two inlet/outlet orifices, or where the coolant fluid passes into a single inlet/outlet orifice disposed between the two inlet/outlet orifices and out of the two inlet/outlet orifices. Either of these configurations results in a parallel fluid flow through the heat sink body.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items or features.

FIG. 1 illustrates a right-side elevation view of a work machine, a perspective view of a power generator and power inverter assembly, and a perspective view of a heat sink according to examples of the present disclosure.

FIG. 2 illustrates an exploded perspective view of a heat sink showing a manifold with two inlet/outlet orifices according to examples of the present disclosure.

FIG. 3 illustrates an exploded perspective view of a heat sink showing a manifold with three inlet/outlet orifices according to an alternative example of the present disclosure.

FIG. 4 illustrates a front elevation view of an extrusion plate according to examples of the present disclosure.

FIG. 5 illustrates a front elevation view of a manifold with two inlet/outlet orifices according to examples of the present disclosure.

FIG. 6 illustrates a side cross-section view of the manifold with two inlet/outlet orifices of FIG. 5.

FIG. 7 illustrates a front elevation view of an alternative extrusion plate according to examples of the present disclosure.

FIG. 8 illustrates a front elevation view of a manifold with three inlet/outlet orifices according to examples of the present disclosure.

FIG. 9 illustrates a side cross-section view of the manifold with three inlet/outlet orifices of FIG. 8.

FIG. 10 illustrates a top cross-section view of the heat sink of FIG. 2 showing a serpentine fluid flow from entering a single inlet/outlet orifice and exiting a single inlet/outlet orifice according to examples of the present disclosure.

FIG. 11 illustrates a top cross-section view of the heat sink of FIG. 3 showing a parallel fluid flow from entering two inlet/outlet orifices and from exiting a single inlet/outlet orifice according to examples of the present disclosure.

FIG. 12 is a partial front elevation view of the extrusion plates of FIGS. 4 and 7 showing turbulators disposed inside extrusion slots according to examples of the present disclosure.

FIG. 13 is a partial front elevation view of the extrusion plate of FIGS. 4 and 7 showing channel fins disposed inside extrusion slots according to examples of the present disclosure.

FIG. 14 is a flow diagram illustrating a method of constructing a heat sink according to examples of the present disclosure.

### DETAILED DESCRIPTION

Wherever possible, the same reference numbers will be used throughout the figures to refer to the same or like parts. In the figures, the left-most digit(s) of a reference number identifies the figure in which the reference number first appears.

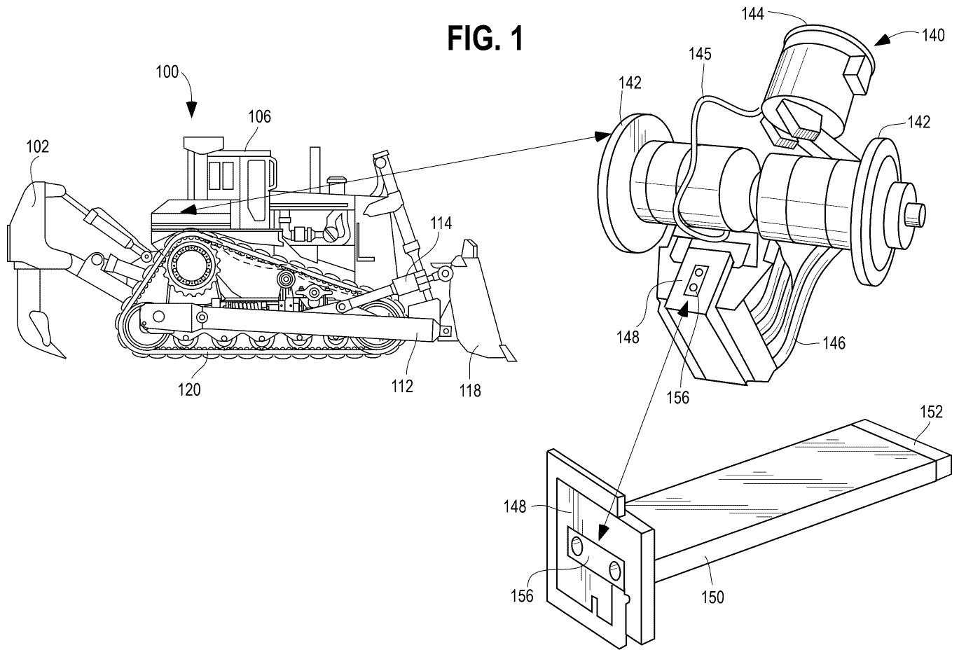

FIG. 1 illustrates a right-side elevation view of a work machine, a perspective view of a power generator and power inverter assembly, and a perspective view of a heat sink according to examples of the present disclosure. As briefly discussed above, machines and systems of various types utilize power inverters for converting DC power to AC power for use by AC power-enabled electrical systems. In some cases, DC power is provided by onboard generators or batteries that needs to be converted to AC power for AC power-enabled systems. In other cases, AC power is generated and received from onboard or standalone generators or AC power providing systems and is converted to DC power for use by DC power-enabled systems. In still other cases, the AC power generated and received from onboard or standalone generators or AC power providing systems is converted to DC power, and then some or all of the DC power is then converted back to AC power for use by AC power-enabled systems (e.g., AC motors).

For example, work machines (e.g., earthmoving machines) automobiles, trucks, recreational vehicles, standalone power generators, and the like often utilize electrical power generators for generating DC power and power inverters for converting the DC power to AC power. The converted AC power may then be used to power onboard electrical systems of mobile machines and/or to provide AC power to structures (e.g., a house, building, etc.). According to examples of the present disclosure, a configurable heat sink for power inverters is provided for dissipating heat generated by an associated power inverter during the process of converting DC power to AC power.

Referring to FIG. 1, for purposes of example, use of a power generator and power inverter is described in association with a work machine 100 on which a power generator and power inverter are deployed. As should be appreciated, use of these systems and devices are equally applicable to other machines such as automobiles, trucks, recreational vehicles, and the like, as well as standalone power generators that may be used provide AC power to standalone structures such as a house, building, temporary structure, and the like.

As illustrated in FIG. 1, a work machine 100 is provided with which various types of work, for example, earthmoving, material moving, and the like may be performed. The work machine 100 illustrates a typical bulldozer-type machine with which material such as dirt, rock, concrete, wood, steel, and the like may be moved from one location to another or may be loaded onto or unloaded from a transport, such as a truck or trailer. The work machine 100, illustrated in FIG. 1, is for purposes of example only and is not limiting of other types of work machines that may be utilized according to examples of the present disclosure. For example, the work machine 100 may include a bulldozer, tractor, large-scale earthmoving machine, and the like. In addition, as will be appreciated, examples of the present disclosure may be utilized with other types of vehicles, including but not limited to automobiles, trucks, trailers, as well as any type of track-enabled machine, and the like.

Referring still to FIG. 1, the work machine 100 includes a cab 106 in which an operator controls the work machine 100. An engine compartment includes space for a combustion engine, hybrid combustion/electric engine/motor combination, an electric motor system for a fully electric work machine, or any other type of prime mover. In addition, the engine compartment may house other systems and components such as transmissions, cabin cooling systems, and the like. Forward of the cab and engine compartment are illustrated components required for movement and use of a work tool attached to the work machine 100. According to examples, the push arms 112 may articulate relative to push arm mounts to raise or lower an attached work tool as required for picking up, dropping and/or pushing material. According to examples, the push arms 112 may articulate relative to the push arm mounts via a suitable motion system 114, such as a hydraulic or pneumatic cylinder system. Rearward of the cab 106 is illustrated a work apparatus 102. As should be appreciated, the work apparatus 102 may include any of a variety of work tools such as backhoes, plows, grader blades, mowing equipment, and the like. Such work tools are well known to those skilled in the art.

At a forward end of the push arms 112, a work tool 118 is provided. According to examples, the work tool 118 is illustrative of a number of different work tools that may be attached to the work machine 100. For example, the work tool 118, illustrated in FIG. 1, is a bucket with which material may be pushed, scooped, lifted, dumped, and the like. Other types of work tools 118 may include blades for pushing material, forks for lifting material such as pallets, and the like. Different types of work tools 118 that may be utilized with the work machine 100 are well known to those skilled in the art. As should be appreciated, the configuration of components of the work machine 100, illustrated in FIG. 1, is for purposes of illustration and example only. That is, according to other types and sizes of work machines, the engine compartment may be forward of the cab, and work tools may be attached to a rear push arm or lifting arm.

Referring still to FIG. 1, the work machine 100 includes a track system 120 for moving the work machine 100 in a forward or backward direction. According to examples, the work machine 100 may be turned by rotating the track system 120 on one side of the work machine 100 in a forward direction while simultaneously rotating a corresponding track system (not shown) on an opposite side of the work machine 100 in a backward direction. The track system 120 includes a track that rotates around a number of track system components in a continuous or infinite movement configuration where the track once secured into position may rotate in a forward or backward direction without interruption other than when the track is stopped or when the direction of movement is changed.

Referring still to FIG. 1, an electric generator/electric motor/power inverter assembly 140 is illustrated. According to examples, the power inverter assembly 140 includes a pair of motors 142 for driving the work machine 100 and associated components. The motors 142 may include a combustion engine, electric motor, a hybrid combustion engine/electric motor, or any other type of prime mover for moving a drive system of the work machine 100. Alternatively, the motors 142 may operate as a separate motor from the work machine drive system for driving a generator 144. In such a case, the motors 142 may be driven by a combustion, electric or hybrid drive system for running the generator 144 for generating DC power.

According to one example, the generator 144 converts mechanical energy (e.g., driven by the motor 142) into DC electrical power based on electromagnetic induction. As understood by those skilled in the art, electromagnetic induction includes moving one or more magnets inside an electrical coil that creates an electrical current that may be used to charge batteries, power electrical components, and/or for moving the work machine 100 or other device by powering an electrical motor. An electrical power cable 145 is illustrated for electrically connecting the generator 144 to the motor 142. DC electrical power may be provided by other systems such as batteries.

According to other examples, the generator 144 may convert mechanical energy into AC electrical power. As understood by those skilled in the art, mechanical energy used to generate either DC power or AC power may come from a variety of sources, for example, combustion, electric or hybrid drive systems. For example, a diesel-electric engine may run a generator that provides AC power output. The AC power output may be used for AC power-enabled systems or may be converted to DC power for DC power-enabled systems.

According to examples of the present disclosure, DC power may be converted to AC power for use in AC power-enabled systems (e.g., DC power received from a battery and converted to AC power), or AC power may be converted to DC power for use in DC power-enabled systems, or AC power may be converted to DC power, and some or all of the DC power may be converted back to AC power for AC power-enabled systems (e.g., AC motors). In the case of AC power to DC power and back to AC power, the AC power may first be passed through a converter to convert the power from AC power to DC power and then through a power inverter (discussed below) for converting the DC power to AC power. For example, AC power may be provided by a standalone generator to a work machine 100 (e.g., via a standalone power supply). At the work machine 100, AC power may be converted to DC power for use by DC power-enabled systems on the work machine 100, and some of the DC power may be converted back to AC power for use by AC power-enabled systems on the work machine 100.

Referring still to FIG. 1, the power inverter assembly 140 includes a power inverter 146 for converting DC power generated by the generator 144 into AC power or for converting DC power previously converted from AC power back to DC power. Power inverters include devices, systems and/or circuitry operative to convert DC power to AC power. As understood by those skilled in the art, the process of converting DC power to AC power via a power inverter 146 produces heat. That is, as DC current flows through components of the power inverter 146 for purposes of converting the DC power to AC power, resistance builds in power inverter components and produces heat. Heat buildup in power inverters can be dissipated according to different methods. For example, a fan may be used to blow cooler air through the power inverter for cooling internal power inverter components. For another example, power inverter heat may be dissipated by use of a heat sink 148.

According to examples of the present disclosure, a configurable heat sink may be adapted to the power inverter 146 for dissipating heat from the power inverter. According to examples, the heat sink 148 is a passive heat exchanger that transfers heat generated by an electronic or mechanical device to a fluid medium such as air, water or chemical fluids (e.g., ethylene glycol). According to examples, the heat sink 148 transfers thermal energy from a higher temperature system such as the power inverter 146. As illustrated in FIG. 1, the heat sink 148 includes a heat sink body 150 configured for insertion into an interior of the power inverter 146 and defining an open space in an interior of the heat sink body through which coolant fluids pass for dissipating heat from the power inverter 146.

According to examples, a manifold 156 is provided through which coolant fluids are passed into and out of the heat sink body 150. According to examples, the manifold is a cast manifold. An end cap 152 is provided for sealing an end of the heat sink body 150 opposite the manifold 156. According to one example, a slot or other opening may be disposed interior of the power inverter 146 for receiving the heat sink 148 as illustrated in FIG. 1. As heat is generated in interior components of the power inverter 146, the heat is absorbed by outer surfaces of the heat sink body 150 and is transferred to the coolant fluid passing through the heat sink body 150.

As described below, use of different manifold configurations (e.g., single inlet/single outlet orifice, double inlet/single outlet orifice and single inlet/double outlet orifice), coolant fluids may be run through coolant channels in series (i.e., serpentine) or in parallel. In addition, use of different extrusion plates allows changing the structures and configurations of extruded fluid coolant channels inside the heat sink body 150. Such manifold and/or fluid coolant channel configurations allows for the freedom to configure heat sinks according to power inverter heat dissipation needs.

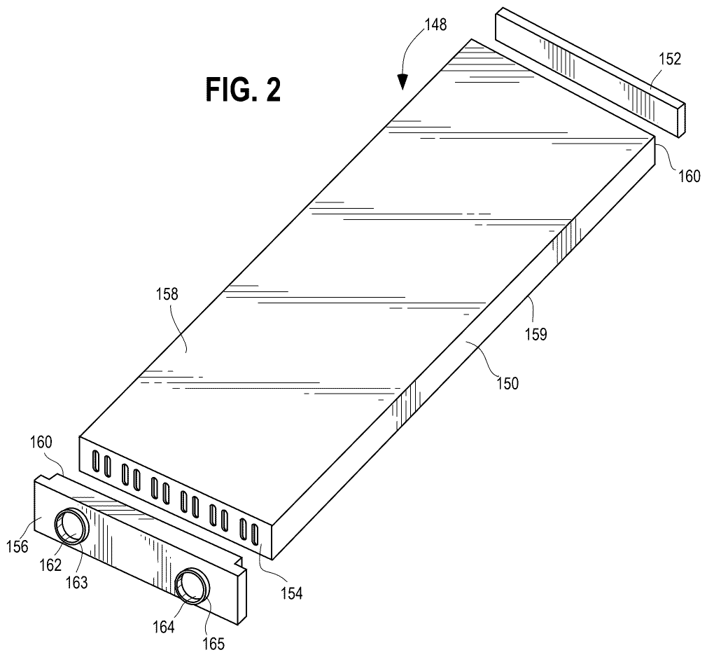

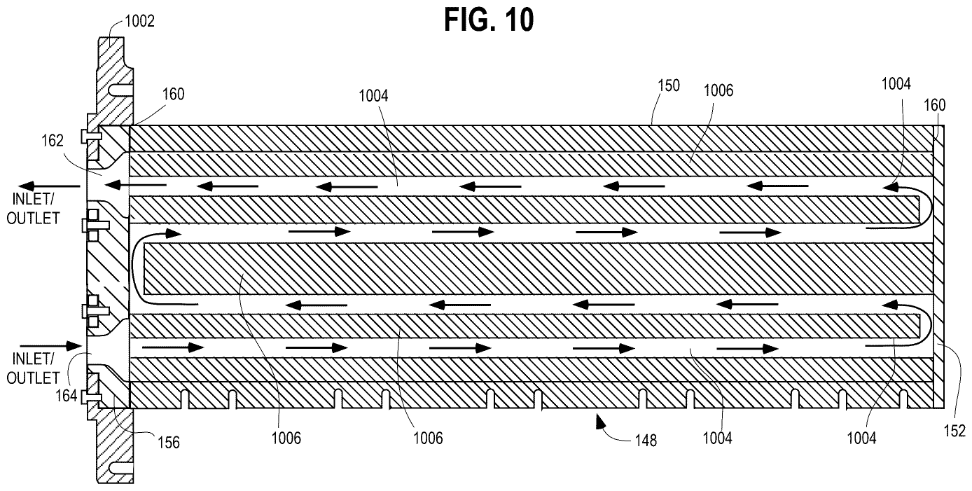

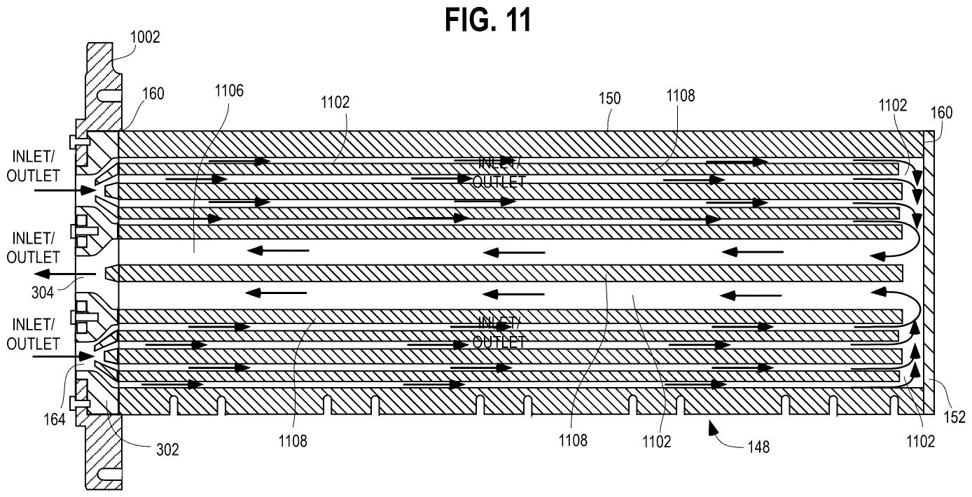

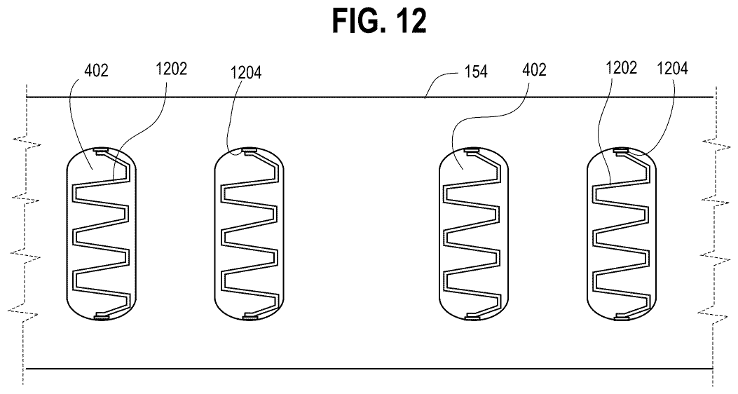

FIG. 2 illustrates an exploded perspective view of a heat sink 148 showing a single inlet/outlet orifice 162 and single inlet/outlet orifice 164 manifold according to examples of the present disclosure. As illustrated in FIG. 2, the heat sink 148 includes a heat sink body 150 through which a coolant fluid passes for cooling the heat sink 148 and for receiving heat transferred to the surfaces of the heat sink body 150 from components of the power inverter 146. According to one example, an upper surface 158 of the heat sink body 150 and a lower surface 159 of the heat sink body 150, as well as side surfaces of the heat sink body 150 absorb heat from interior components of the power inverter 146 which is then transferred to coolant fluid passing through one or more coolant fluid channels disposed in the interior of the heat sink body 150 as illustrated and described below with reference to FIGS. 10 and 11. That is, according to examples, the heat sink body 150 includes one or more external surfaces configured to absorb heat from an interior of the heat sink body 150 of the power inverter 146.

As illustrated in FIG. 2, the manifold 156 is configured for attachment to a first end of the heat sink body and includes inlet/outlet and inlet/outlet orifices 162, 164 for providing a fluid passage into one or more fluid channels disposed in the heat sink body 150. According to examples, an inlet/outlet orifice 162 and an inlet/outlet orifice 164 are provided through which coolant fluid passes into and out of the heat sink body 150. As should be appreciated, the coolant fluids may pass into the heat sink body 150 through either the inlet/outlet orifice 162 or the inlet/outlet orifice 164. According to examples, the protruding rims 163, 165 may be used for affixing hoses or tubes to the inlet/outlet orifices 162, 164 for passing coolant fluids into and out of the heat sink body 150 via the manifold 156.

Coolant fluid heated by heat transfer from components of the power inverter 146 is circulated out of the heat sink body 150 via the manifold 156 as cooler fluid is circulated into the heat sink body 150 via the manifold 156. Circulation of coolant fluid into and out of the heat sink body 150 receives and transfers heat out on the power inverter 146. According to examples, as coolant fluid is heated by transfer of heat to the coolant fluid, the heated coolant fluid exits the heat sink body 150 and is cooled by passing it through a cooling medium (e.g., via a radiator system) or by passing it through a cooling system such as a fluid chiller or heating, ventilation, and air (HVAC) cooling system. Circulation of coolant fluid through the heat sink body 150 is illustrated and described below with reference to FIGS. 10 and 11.

Referring still to FIG. 2, an extrusion plate 154 (or “plate”) is affixed to a first end of the heat sink body and is provided through which a material is extruded to form channels inside the heat sink body 150 through which coolant fluids are passed for dissipating heat from the power inverter 146. That is, the plate has a plurality of slots fluidly connected to respective fluid channels in the heat sink body. According to examples, the manifold 156 and the end cap 152 are mated to the heat sink body 150 to form the heat sink 148, as illustrated in FIG. 1. The manifold 156 and the end cap 152 may be secured to the heat sink body 150 according to a number of different methods. For example, a joint between the manifold 156 and the heat sink body 150 and a joint between the end cap 152 and the heat sink body 150 may be performed by one or more binding processes. According to examples, joints may be formed from a number of process, for example, welding, brazing, and the like. According to one example, the joints are formed using a structural adhesive to bond the manifold 156 and the end cap 152 to the respective ends of the heat sink body 150.

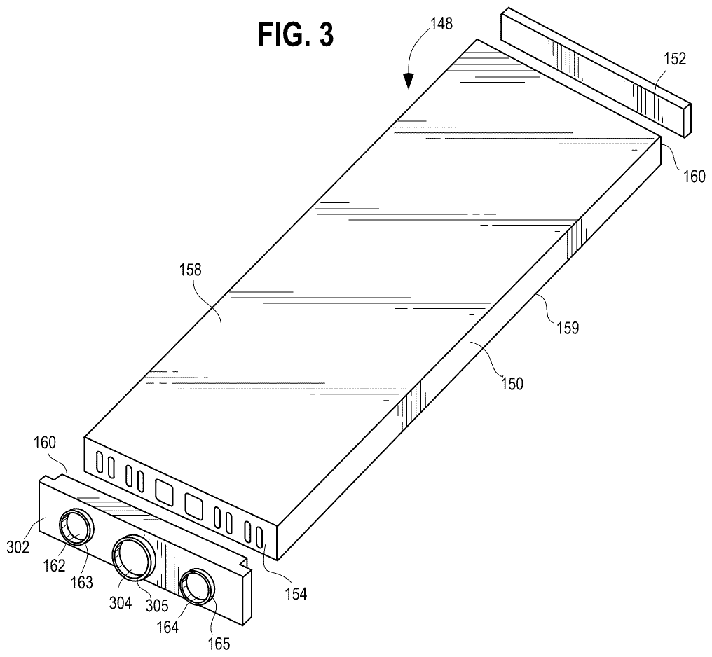

FIG. 3 illustrates an exploded perspective view of a heat sink showing a manifold with three inlet/outlet orifices according to an alternative example of the present disclosure. The manifold 302 includes double inlet/outlet orifices 162, 164 and a single inlet/outlet orifice 304. According to this example of the present disclosure, both inlet/outlet orifices 162, 164 are used as inlets for passing coolant fluid into the heat sink body 150, and the single inlet/outlet orifice 304 is used to pass coolant fluid out of the heat sink body 150. In this case, the single inlet/outlet orifice 304 is positioned between the inlet/outlet orifices 162, 164. Alternatively, the single inlet/outlet orifice 304 may be used as an inlet for passing coolant fluid into the heat sink body 150, and the double inlet/outlet orifices 162, 164 may be used for passing coolant fluid out of the heat sink body 150. According to examples, the protruding rims 163, 165 of the inlet/outlet orifices 162, 164 and the protruding rim 305 of the single inlet/outlet orifice 304 may be used for affixing hoses or tubes to the inlet/outlet orifices 162, 164 and inlet/outlet orifice 304 for passing coolant fluids into and out of the heat sink body 150 via the manifold 156.

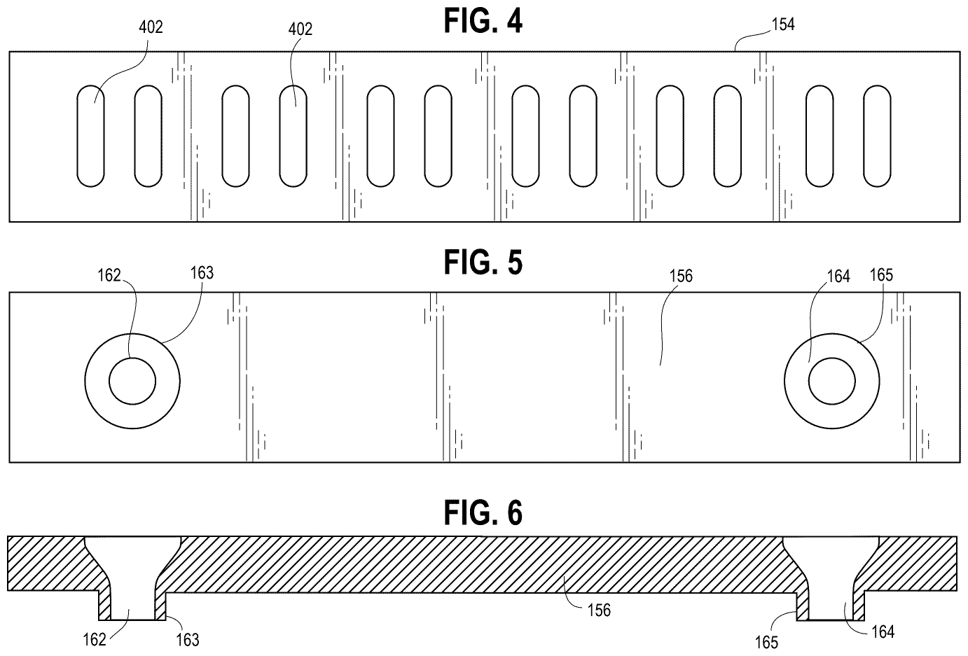

FIG. 4 illustrates a front elevation view of an extrusion plate according to examples of the present disclosure. According to examples, the extrusion plate 154 serves as a die through which a material may be extruded to generate coolant fluid channels inside the heat sink body 150 through which coolant fluids may be circulated for dissipating heat from the power inverter 146. As illustrated in FIG. 4, a number of extrusion slots are provided in the extrusion plate 154 through which a suitable extrusion material may be extruded. According to examples, suitable extrusion materials may include plastics, thermoplastics, engineered plastics, aluminum alloys, and the like. As should be appreciated, the extrusion material selected for extruding coolant fluid channels may be selected based on a number of factors including anticipated temperatures that may be experienced by the extruded coolant fluid channels, anticipated coolant fluid pressures that may be experienced by the extruded coolant fluid channels, and the like. As should be appreciated, numbers and orientations of the extrusion slots 402 may be varied to generate different coolant fluid channels as desired for different heat sink configurations. That is, as illustrated and described below with reference to FIGS. 10 and 11, different coolant fluid channel configurations may be utilized to provide different levels of heat dissipation for different power inverter configurations.

FIG. 5 illustrates a front elevation view of a manifold with two inlet/outlet orifices according to examples of the present disclosure. According to examples, a manifold 156 may include a fluid distribution device that assists in distribution of a fluid from a source to one or more fluid outlets or vice versa. In this case, the manifold 156 distributes a fluid from outside the heat sink body 150 into a serpentine fluid flow path or a parallel flow fluid flow path (see FIGS. 10 and 11) for efficiently transferring heat from the power inverter 146 to the fluid circulating through heat sink body 150. As described above, the manifold 156 includes inlet/outlet orifices 162, 164 that be used to flow coolant fluids into and out of the heat sink body 150 for dissipating heat from the power inverter 146. According to examples, use of a single inlet/outlet orifice for passing coolant fluid into the heat sink body 150 and a single inlet/outlet orifice for passing coolant fluid out of the heat sink body 150 provides for a serpentine coolant fluid flow in the heat sink body 150 as illustrated and described below with reference to FIG. 10. The orifice protruding rims 163 and 165 provide connection points for hoses or tubes through which coolant fluids may pass into and out of the inlet/outlet orifices 162, 164.

FIG. 6 illustrates a side cross-section view of the manifold with two inlet/outlet orifices of FIG. 5. As illustrated in FIG. 6, the inlet/outlet orifices 162, 164 have a narrow forward diameter that flares out to a wider diameter at the backside of the manifold 156 at which the manifold 156 is connected to the extrusion plate 154 and to one end of the heat sink body 150 as illustrated in FIG. 2. The geometry of the inlet/outlet orifices 162, 164 illustrated in FIG. 6 is configured to accommodate coolant fluid flow into and out of the heat sink body 150 as illustrated and described below with reference to FIG. 10. As should be appreciated, the geometry of the inlet/outlet orifices 162, 164 may be varied to accommodate different fluid inlet and outlet flow rates and pressures desired for different heat sink configurations and heat dissipation demands.

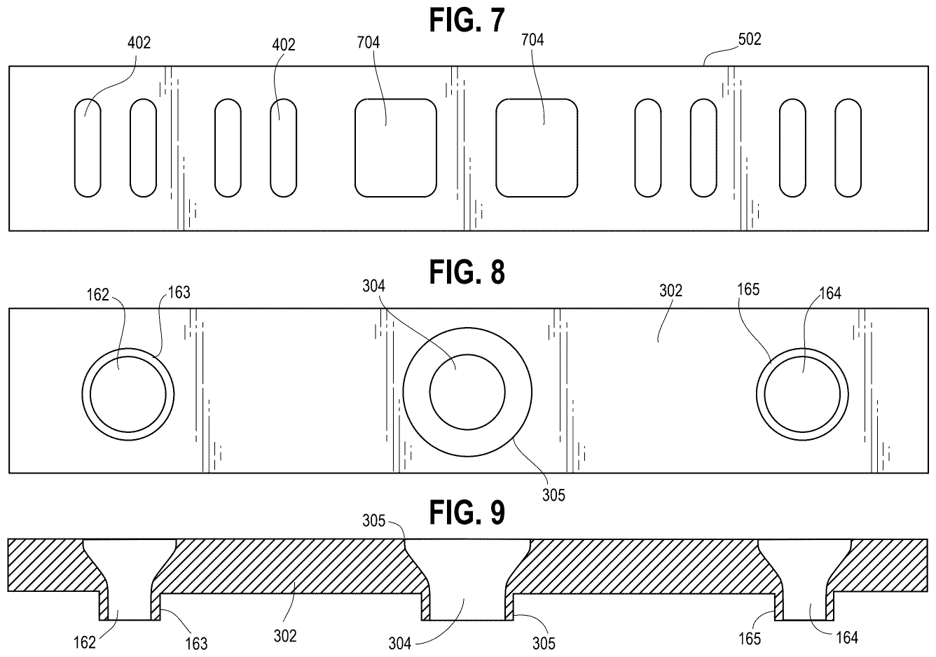

FIG. 7 illustrates a front elevation view of an alternative extrusion plate 502 according to examples of the present disclosure. As illustrated in FIG. 7, a pair of extrusion slots 704 are illustrated as larger than extrusion slots 402. The configurations of extrusion slots 704 allow for increasing the extrusion volume into the heat sink body 150 to generate larger coolant fluid channels inside the heat sink body 150. According to examples, the larger coolant fluid channels may accommodate a larger single inlet/outlet orifice 304 as illustrated in FIG. 3 and below in FIGS. 8 and 9. As should be appreciated, the extrusion slots 704 are for purposes of example and are not limiting of other extrusion slot configurations that may be required to accommodate different outlet sizes for configurations.

FIG. 8 illustrates a front elevation view of a manifold with three inlet/outlet orifices according to examples of the present disclosure. As illustrated in FIG. 8, according to this alternative manifold example, the manifold 302 includes two inlet/outlet orifices 162, 164 and a single inlet/outlet orifice 304. According to examples, coolant fluid may pass into the heat sink body 150 through the two inlet/outlet orifices 162, 164 and out of the single inlet/outlet orifice 304, or coolant fluid may pass into the heat sink body 150 through the single inlet/outlet orifice 304 and out of the double inlet/outlet orifices 162, 164. In either case, use of this manifold 302 provides for a parallel coolant fluid flow in the heat sink body 150 as illustrated and described below with reference to FIG. 11.

FIG. 9 illustrates a side cross-section view of the manifold with three inlet/outlet orifices of FIG. 8. As illustrated in FIG. 9, the inlet/outlet orifices 162, 164 and the inlet/outlet orifice 304 have a narrow forward diameter that flares out to a wider diameter at the backside of the manifold 302 at which the manifold 302 is connected to the extrusion plate 154 and to one end of the heat sink body 150 as illustrated in FIG. 3. The geometry of the inlet/outlet orifices 162, 164 and the inlet/outlet orifice 304 illustrated in FIG. 9 is configured to accommodate coolant fluid flow into and out of the heat sink body 150 as illustrated and described below with reference to FIG. 11. As should be appreciated, the geometry of the inlet/outlet orifices 162, 164 and the inlet/outlet orifice 304 may be varied to accommodate different fluid inlet and outlet flow rates and pressures desired for different heat sink configurations and heat dissipation demands.

Referring still to FIGS. 4 and 7, according to an alternative example, instead of extruding the coolant fluid channels, coolant fluid channels may be constructed in the heat sink body 150 during assembly of the heat sink body 150. In this case, coolant fluid channels (see FIGS. 10 and 11) may be manufactured outside the heat sink body 150 and subsequently may be inserted into the heat sink body 150 during manufacture of the heat sink body 150.

FIG. 10 illustrates a top cross-section view of the heat sink of FIG. 2 showing a serpentine fluid flow from entering a single inlet/outlet orifice and exiting a single inlet/outlet orifice according to examples of the present disclosure. As illustrated in FIG. 10, the manifold 156 is bonded to a first end of the heat sink body 150, and the end cap 152 is bonded to a second end of the heat sink body 150. As discussed above, according to one example, the manifold 156 and the end cap 152 may be bonded together according to a number of processes including welding, brazing and the like. According to examples, bonding to the heat sink body 150 may use a structural adhesive 160. Referring still to FIG. 10, by use of the extrusion plate 154 described above with respect to FIG. 4, coolant fluid channels 1004 are generated by extruding material through the extrusion slots 402 (FIG. 4) to create extruded fluid channel guides 1006.

According to the example coolant fluid channels 1004 illustrated in FIG. 10, use of a single inlet/outlet orifice 164 and a single inlet/outlet orifice 162 provides for a serpentine coolant fluid flow through the heat sink body 150. According to examples, a single inlet and single outlet configuration and resulting serpentine coolant fluid flow may be utilized for power inverters for which the resultant coolant fluid flow rate and heat dissipation capacity are required. As should be appreciated, for different power inverters, longer or shorter heat sink bodies may be utilized with different (e.g., more or less) coolant fluid channels. To increase or decrease the number of coolant fluid channels, the number and configurations of the extrusion slots 402 of the extrusion plate 154 (FIG. 4) may be modified.

FIG. 11 illustrates a top cross-section view of the heat sink of FIG. 3 showing a parallel fluid flow from entering two inlet/outlet orifices and from exiting a single inlet/outlet orifice according to examples of the present disclosure. As illustrated in FIG. 11, the manifold 302 is bonded to a first end of the heat sink body 150, and the end cap 152 is bonded to a second end of the heat sink body 150. As discussed above, according to one example, the manifold 156 and the end cap 152 are bonded to the heat sink body 150 using a structural adhesive 160. Referring still to FIG. 11, by use of the extrusion plate 154 described above with respect to FIG. 7, coolant fluid channels 1102 are generated by extruding material through the extrusion slots 402, 704 (FIG. 7) to create extruded fluid channel guides 1108.

According to the example coolant fluid channels 1102 illustrated in FIG. 11, use of two inlet/outlet orifices 162, 164 and a single inlet/outlet orifice 304 provides for a parallel coolant fluid flow through the heat sink body 150. According to examples, a double inlet and single outlet configuration and resulting parallel coolant fluid flow may be utilized for power inverters for which the resultant coolant fluid flow rate and heat dissipation capacity are required. As should be appreciated, for different power inverters, longer or shorter heat sink bodies may be utilized with different (e.g., more or less) coolant fluid channels. To increase or decrease the number of coolant fluid channels, the number and configurations of the extrusion slots 402, 704 of the extrusion plate 154 (FIG. 7) may be modified.

FIG. 12 is a partial front elevation view of the extrusion plates of FIGS. 4 and 7 showing turbulators 1202 disposed inside extrusion slots according to examples of the present disclosure. As understood by those skilled in the art, the transfer of heat to a fluid medium may be made more efficient based on the flow of the fluid medium. As described above, according to examples, heat is transferred to the coolant fluid passing through the heat sink body 150 by transfer of heat from components of the power inverter 146 to outer surfaces of the heat sink body 150 and then into coolant fluid passing through the coolant fluid channels 1004, 1102 (FIGS. 10, 11). According to examples, turbulent flow of coolant fluids through the coolant fluid channels causes increased contact of coolant fluids with the inner surfaces of the heat sink body 150. That is, a smooth or laminar flow of coolant fluid through the fluid coolant channels does not contact the inner surfaces of the heat sink body 150 as well as turbulent flow as turbulent flow causes the coolant fluid to more aggressively contact the inner surfaces of the cooling fluid channels. As a result, heat transfer through the outer surfaces of the heat sink body 150 to coolant fluid passing through the heat sink body is increased.

According to examples, turbulators 1202 are disposed inside the coolant fluid channels, and flow of coolant fluids past the turbulators causes fluid flow through the fluid channels to be turbulent flow. That is, according to examples, each of the one or more coolant fluid channels may include a turbulator disposed therein for causing fluid flow through the one or more coolant fluid channels to form a turbulent flow. According to examples, the turbulators 1202 may be configured according to a number of designs. The turbulators 1202, illustrated in FIG. 12, are configured in a zig zag design. However, as should be understood, other designs may be utilized when more or less turbulence in the coolant fluid flow is desired. As illustrated in FIG. 12, the turbulators 1202 are bonded to the insides of the coolant fluid channels at bonding sites 1204. The turbulators may be bonded by welding, brazing, structural adhesives, or the like. According to examples, the turbulators may run the full length of coolant fluid channels, or the turbulators 1202 may run partial lengths of the coolant fluid channels.

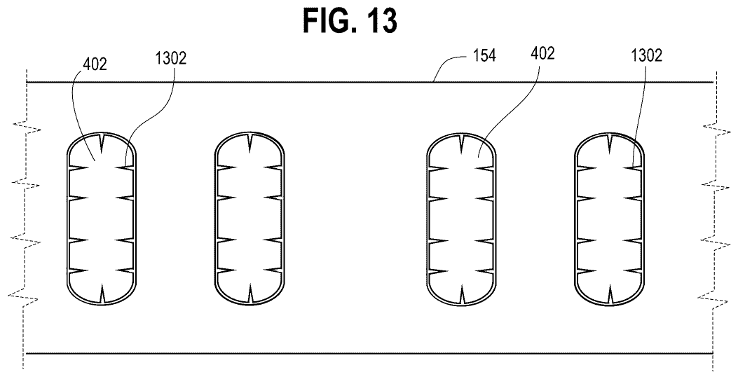

FIG. 13 is a partial front elevation view of the extrusion plate 154 of FIGS. 4 and 7 showing channel fins 1302 disposed inside extrusion slots 402 according to examples of the present disclosure. That is, according to examples, each of the one or more coolant fluid channels may include one or more channel fins disposed therein for causing fluid flow through the one or more coolant fluid channels to form a turbulent flow. As illustrated in FIG. 13, instead of using turbulators 1202, as illustrated in FIG. 12, channel fins 1302 may be utilized in the coolant fluid channels to generate turbulent fluid flow inside the coolant fluid channels. According to one example, the channel fins 1302 may be configured in the extrusion slots 402. Thus, when the coolant fluid channels are created by extrusion of an extrusion material through the extrusion slots 402, 704 channel fins 1302 will be generated through the length of the extruded coolant fluid channels.

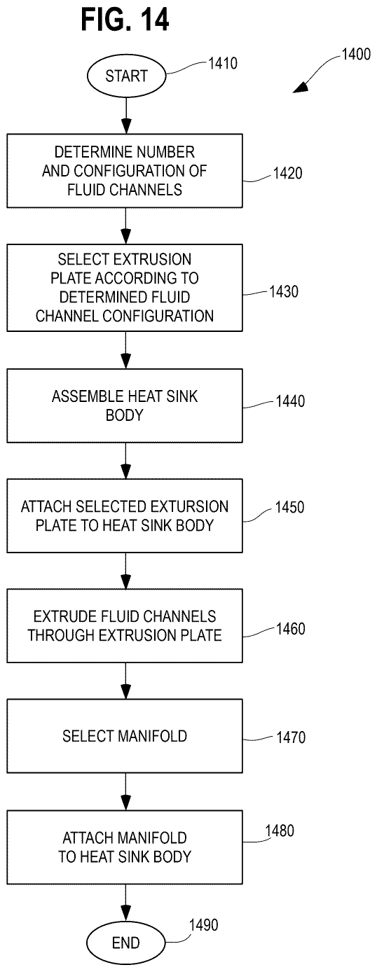

FIG. 14 is a flow diagram illustrating a method of constructing a heat sink 148 according to examples of the present disclosure. The method 1400 begins at start operation 1410 and proceeds to operation 1420 where a number and configuration of coolant fluid channels for disposition in an interior of the heat sink body 150 is determined. According to one example the determination may be based on a heat profile or heat characteristics of a power inverter 146 for which the heat sink 148 is being constructed.

At operation 1430, an extrusion plate 154 is selected according to the determined coolant fluid channels determination. At operation 1440, the heat sink body 150 is assembled. At operation 1450 the extrusion plate 154 is affixed to the heat sink body 150.

At operation 1460, coolant fluid channels 1004, 1102 are extruded through extrusion slots 402 of the extrusion plate 154.

At operation 1470, a manifold 156, 302 is selected. If it is desired that the heat sink 148 will have a serpentine fluid flow, then a manifold 156 with a single inlet/outlet orifice and a single inlet/outlet orifice is selected. As mentioned herein, the each of the inlet/outlet orifices 162, 164 may be used as an inlet orifice or as an outlet orifice, and the resulting serpentine fluid flow will be reversed depending on which of the inlet/outlet orifices 162, 164 is used as an inlet versus an outlet. If it is desired that the heat sink 148 will have a parallel fluid flow, then a manifold 302 with a double inlet/outlet orifice and a single inlet/outlet orifice is selected. As mentioned herein, the three inlet/outlet configuration may include two inlet orifices with a single outlet orifice disposed between the two inlet orifices or may include two outlet orifices with a single inlet orifice disposed between the two outlet orifices. Either of these inlet/outlet configurations results in a parallel fluid flow through the heat sink body 150. At operation 1480, the manifold 156, 302 is attached to the heat sink body 150 by a structural adhesive 160.

As described above, according to examples, instead of extrusion of coolant fluid channels 1004, 1102, the coolant fluid channels may be manufactured outside the heat sink body 150 and may be inserted into the heat sink body 150 during manufacture of the heat sink body 150. Turbulators 1202 or channel fins 1302 may be added to the coolant fluid channels as part of the extrusion process, or turbulators 1202 and channel fins 1302 may be manufactured inside the coolant fluid channels 1004, 1102 and may be added to the coolant fluid channels prior to installation of the coolant fluid channels in the heat sink body 150.

The method 1400 ends at operation 1490.

### INDUSTRIAL APPLICABILITY

According to examples of the present disclosure, a configurable heat sink for power inverters is provided for dissipating heat generated by an associated power inverter during the process of converting DC power to AC power, or for converting AC power to DC power, or for converting AC power to DC power and back to AC power as may be required for various purposes. For example, DC power may be provided by one or more sources such as a generator, battery or standalone system, and the DC power may require conversion to AC power to operate AC power-enabled systems. Alternatively, AC power may be provided by one or more sources, and the AC power may require conversion to DC power to operate DC power-enabled systems.

As described herein, the heat sink of the present disclosure allows for configuration of the heat sink to optimize power inverter heat dissipation by modifying heat sink manifold design and coolant fluid channel configurations. Through use of different manifold designs (e.g., single inlet/single outlet, double inlet/single outlet, and double outlet/single inlet), coolant fluids may be run through coolant channels in series (i.e., serpentine) or in parallel. In addition, use of different extrusion plates allows for changing the structures and configurations of extruded coolant fluid channels inside the heat sink body. Such manifold and/or coolant fluid channel configurations allow for the freedom to configure heat sinks according to power inverter heat dissipation needs.

The configurable heat sink may include coolant fluid channels inside a heat sink body through which coolant fluid circulates. Heat from internal components of the power inverter is absorbed by outer surfaces of the heat sink body and by the coolant fluids circulating through the coolant fluid channels. A first manifold may be utilized for directing coolant fluid into and out of the heat sink body. The first manifold includes a single inlet/outlet orifice through which coolant fluid enters the heat sink body and a single inlet/outlet orifice through which heated coolant fluid exits the heat sink body. Use of the single inlet/single outlet orifice manifold causes coolant fluid to follow a serpentine flow through the heat sink body for dissipating heat from the power inverter. A second manifold includes two inlet/outlet orifices through which coolant fluid enters the heat sink body and a single inlet/outlet orifice through which heated coolant fluid exits the heat sink body. Alternatively, the second manifold may include a single inlet/outlet orifice through which coolant fluid enters the heat sink body and two inlet/outlet orifices through which coolant fluid exits the heat sink body. One of the first or second manifolds may be applied to the heat sink body based on the heat dissipation needs of a given power inverter heat profile. Advantageously, a manifold is affixed to the heat sink body using a structural adhesive instead of other method such as welding which reduces weight and manufacturing complexity and cost of the heat sink.

An extrusion plate may be affixed to the heat sink body through which an extrusion material is extruded for generating the coolant fluid channels inside the heat sink body. By altering numbers and sizes of extrusion slots in the extrusion plate, the numbers and sizes of extruded coolant fluid channels may be modified to adapt the resulting heat sink to the heat dissipation needs of a given power inverter.

In order to enhance the heat dissipation of the coolant fluids circulating through the heat sink body, turbulators or channel fins may be installed or extruded into the coolant fluid channels. The turbulators or channel fins cause circulating coolant fluid to experience turbulent flow though the heat sink. Turbulent flow of coolant fluid against interior surfaces of the heat sink body causes the coolant fluid to absorb heat from outside the heat sink body more efficiently.

While aspects of the present disclosure have been particularly shown and described with reference to the embodiments above, it will be understood by those skilled in the art that various additional embodiments may be contemplated by the modification of the disclosed machines, systems, and methods without departing from the spirit and scope of what is disclosed. Such embodiments should be understood to fall within the scope of the present disclosure as determined based upon the claims and any equivalents thereof.

1. A heat sink, comprising:
a heat sink body, the heat sink body defining an open space in an interior of the heat sink body for receiving one or more fluid channels;
a plate affixed to a first end of the heat sink body, the plate having a plurality of slots fluidly connected to respective fluid channels of the one or more fluid channels;
an end cap affixed to a second end of the heat sink body; and
a manifold affixed to the first end of the heat sink body, the plate disposed between the manifold and the first end of the heat sink body, the manifold including
a first inlet orifice providing fluid passage into the one or more fluid channels, and
an outlet orifice providing fluid exit from the one or more fluid channels.

2. The heat sink of claim 1, wherein the first inlet orifice, the outlet orifice, and the one or more fluid channels provide a serpentine fluid flow path from the first inlet orifice, through the one or more fluid channels, to the outlet orifice.

3. The heat sink of claim 1, wherein the manifold includes a second inlet orifice providing fluid passage into the one or more fluid channels, the outlet orifice being positioned between the first inlet orifice and the second inlet orifice.

4. The heat sink of claim 3, wherein a first fluid flow path is formed from the first inlet orifice to the outlet orifice and a second fluid flow path is formed from the second inlet orifice to the outlet orifice where the first fluid flow path is parallel to the second fluid flow path.

5. The heat sink of claim 1, each of the one or more fluid channels having a turbulator disposed therein, the turbulator configured to cause a fluid passing through each of the one or more fluid channels to form a turbulent flow.

6. The heat sink of claim 1, each of the one or more fluid channels having one or more channel fins disposed therein, the one or more channel fins configured to cause a fluid passing through each of the one or more fluid channels to form a turbulent flow.

7. The heat sink of claim 1, wherein:
the heat sink body is configured for insertion into an interior of a power inverter;
one or more external surfaces of the heat sink body are configured to absorb heat from the interior of the power inverter; and
the heat from the interior of the power inverter is transferred from the one or more external surfaces of the heat sink body to a fluid passing through the one or more fluid channels.

8. The heat sink of claim 1, wherein the manifold is affixed to the heat sink body with a structural adhesive.

9. The heat sink of claim 5, wherein the manifold is a cast manifold.

10. A configurable heat sink manifold, comprising:
a manifold body, the manifold body configured for attachment to a first end of a heat sink body;
the manifold body including a first inlet orifice providing fluid passage into a fluid channel disposed in an interior open space of the heat sink body;
the manifold body including a first outlet orifice providing fluid passage out of the fluid channel disposed in the interior open space of the heat sink body; and
wherein the first inlet orifice, the first outlet orifice, and the fluid channel provide a serpentine fluid flow path from the first inlet orifice through the fluid channel and out through the first outlet orifice.

11. The configurable heat sink manifold of claim 10, wherein the manifold body includes a second outlet orifice providing fluid passage out of the fluid channel, the first inlet orifice being positioned between the first outlet orifice and the second outlet orifice.

12. The configurable heat sink manifold of claim 11, wherein a first fluid path is formed from the first inlet orifice to the first outlet orifice and a second fluid path is formed from the first inlet orifice to the second outlet orifice where the first fluid path is parallel to the second fluid path.

13. The configurable heat sink manifold of claim 10, the fluid channel having a turbulator, the turbulator configured to cause a fluid passing through the fluid channel to form a turbulent flow.

14. The configurable heat sink manifold of claim 10, the fluid channel having one or more channel fins, the one or more channel fins configured to cause a fluid passing through the fluid channel to form a turbulent flow.

15. A method of constructing a heat sink, comprising:
determining a number and configuration of one or more fluid channels for disposition in a heat sink body;
selecting a plate for the one or more fluid channels for disposition in an interior of a heat sink body;
disposing the one or more fluid channels in the interior of a heat sink body;
selecting a manifold for passing a coolant fluid into the one or more fluid channels in the interior of the heat sink body; and
attaching the manifold to a first end of the heat sink body over the plate.

16. The method of claim 15, wherein selecting a manifold for passing a coolant fluid into the one or more fluid channels in the interior of the heat sink body includes selecting a manifold including a first inlet orifice providing fluid passage into the one or more fluid channels in the interior of a heat sink body and including an outlet orifice providing fluid exit from the one or more fluid channels in the interior of a heat sink body.

17. The method of claim 15, wherein selecting a manifold including a first inlet orifice providing fluid passage into the one or more fluid channels in the interior of a heat sink body and including an outlet orifice providing fluid exit from the one or more fluid channels in the interior of a heat sink body includes selecting a manifold providing a serpentine fluid flow path from the first inlet orifice through the one or more fluid channels in the interior of a heat sink body and out through the outlet orifice.

18. The method of claim 16, wherein selecting a manifold for passing a coolant fluid into the one or more fluid channels in the interior of the heat sink body includes selecting a manifold including a second inlet orifice providing fluid passage into the one or more fluid channels in the interior of a heat sink body, the outlet orifice being positioned between the first inlet orifice and second inlet orifice.

19. The method of claim 18, wherein selecting a manifold including first and second inlet orifices providing fluid passage into the one or more fluid channels in the interior of a heat sink body includes providing a parallel fluid flow path from the first and second inlet orifices through the one or more fluid channels in the interior of a heat sink body and out through the outlet orifice.

20. The method of claim 15, prior to disposing the one or more fluid channels in the interior of a heat sink body, assembling the heat sink body and configuring the heat sink body for insertion into an interior of a power inverter for transferring heat from the power inverter to the heat sink body.
